(19) United States
(12) Patent Application Publication
(10) Pub. No.: US 2007/0072418 A1
(43) Pub. Date: Mar. 29, 2007

(54) Method of forming tungsten silicide layer and method of fabricating semiconductor element using same

(76) Inventors: Jang-hee Lee, Yongin-si (KR); Jae-hwa Park, Yongin-si (KR); Hee-sook Park, Seoul (KR); Byung-hee Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/524,298

(22) Filed: Sep. 21, 2006

(30) Foreign Application Priority Data
Sep. 23, 2005 (KR) 10-2005-0088905

(51) Int. Cl. H01L 21/44

(52) U.S. Cl. 438/683; 438/685

(57) ABSTRACT

A method of forming a tungsten silicide layer and a related method of fabricating a semiconductor element. The method of forming the tungsten silicide layer includes forming a pre-coating layer within a CVD process chamber by injecting a tungsten source gas (A) and a silicon source gas (B) at a flow ratio (A/B) of 1/50 or less, and thereafter loading a semiconductor substrate into the CVD process chamber in which the precoating layer is formed, and injecting additional tungsten source gas and silicon source gas to form the tungsten silicide layer on the semiconductor substrate.

### BACKGROUND OF THE INVENTION

1. Field of the Invention

Embodiments of the invention relate to a method of forming a metal silicide layer and a method of fabricating a semiconductor element incorporating same. More particularly, embodiments of the invention relate to a method of forming a tungsten silicide layer using a Chemical Vapor Deposition (CVD) process and a method of fabricating a semiconductor element incorporating same.

This application claims priority from Korean Patent Application No. 10-2005-0088905 filed on Sep. 23, 2005, the subject matter of which is hereby incorporated by reference in its entirety.

2. Description of the Related Art

Contemporary semiconductor devices are characterized by competing demands for increased integration density, increased operating speed, and reduced power consumption. Integration density is increased by reducing the size of fabrication patterns used to define constituent semiconductor elements. The width of a gate line, junction depths for source/drain regions, and cross-sectional area of an electrical contact are all examples of semiconductor element features subject to size reduction as integration density increases. Unfortunately, reductions in the pattern dimensions of various semiconductor elements may actually result in an increased electrical resistance (or impedance) for the elements. And increased electrical resistance (or impedance) impedes desirable reductions in semiconductor device operating speed and power consumption.

To address this problem, refractory metals such as tungsten, having a relatively low sheet resistance (e.g., 2 to 4 Ω/SQ), have been used to form various elements in contemporary semiconductor devices. For example, refractory metal layers have been used to form gate lines, bit lines, and similar wiring structures in various semiconductor devices.

Unfortunately, if a refractory metal layer is used all by itself to form a gate line, contamination of a corresponding gate insulating layer may occur. Accordingly, a composite (e.g., a laminated) structure is used to implement the gate line which includes one or more buffer layers (e.g., doped polysilicon) and a refractory metal line. However, when a refractory metal layer is directly laminated on a polysilicon layer, the contact resistance of the resulting composite structure increases. Accordingly, an ohmic contact layer (e.g., a metal silicide layer) is typically interposed between the polysilicon layer and the refractory metal layer.

When a tungsten silicide layer is used as an ohmic contact layer, for example, the refractory metal layer may be easily silicidated during a subsequently applied, high temperature heat treatment process (hereafter a “thermal annealing process”). This relatively easy process is, however, such to several problems. For example, if the upper portion of the refractory metal layer is silicidated, a resulting gate electrode may have an undesired resistance. Furthermore, silicidation of the refractory metal layer may result in voids being formed at an interface between the polysilicon layer and the tungsten silicide layer.

To avoid these problems, efforts have been made to change the composition of the ohmic contact layer. In one suggested approach, the ohmic contact layer is formed using a CVD deposition method. However, this approach has proved problematic in several ways. For example, when a pre-coating condition for the CVD process chamber is undesirable for the particular composition of the ohmic contact layer being formed, contamination particles may be generated. This potential outcome necessitates the frequent cleaning of the CVD process chamber. However, frequent cleaning of the CVD process chamber is uneconomical in terms of loss fabrication time and wear and tear of the constituent equipment. For example, the lifespan of the shower head assembly commonly used in CVD process chambers may be significantly reduced due to frequent cleaning procedures.

### SUMMARY OF THE INVENTION

In one embodiment, the invention provides a method of forming a tungsten silicide layer on a semiconductor substrate in a Chemical Vapor Deposition (CVD) process chamber, the method comprising; forming a pre-coating layer on the interior of the CVD process chamber by injecting a tungsten source gas (A) and a silicon source gas (B) at a flow ratio (A/B) of 1/50 or less, and thereafter loading the semiconductor substrate into the CVD process chamber, and injecting additional tungsten source gas and silicon source gas to form the tungsten silicide layer on the semiconductor substrate.

In another embodiment, the invention provides a method of fabricating a semiconductor element on a semiconductor substrate, the method comprising; forming a pre-coating layer in a Chemical Vapor Deposition (CVD) process chamber by injecting a tungsten source gas (A) and a silicon source gas (B) at a flow ratio (A/B) of 1/50 or less, and thereafter loading the semiconductor substrate into the CVD process chamber, wherein the semiconductor substrate comprises a gate insulating layer and a polysilicon layer formed on the gate insulating layer, and injecting additional tungsten source gas and silicon source gas to form a tungsten silicide layer on the polysilicon layer.

### BRIEF DESCRIPTION OF THE DRAWINGS

FIGS. 1A to 1D are sectional views sequentially showing a process of forming a tungsten silicide layer according to an embodiment of the present invention;

FIGS. 2A to 2D are sectional views sequentially showing a process of fabricating a semiconductor element according to the embodiment of the present invention; and

FIG. 3 is a graph showing the number of particles generated with respect to the total deposition thickness (the number of processed substrates) in an example and a comparative example.

### DESCRIPTION OF EMBODIMENTS

Advantages and features of the present invention and methods of accomplishing the same may be understood more readily by reference to the following description of embodiments and the accompanying drawings. The present invention may, however, be embodied in many different forms and should not be construed as being limited to only the embodiments set forth herein. Rather, these embodiments are provided as teaching examples. Throughout the written description and accompanying drawings, like reference numerals refer to like or similar elements.

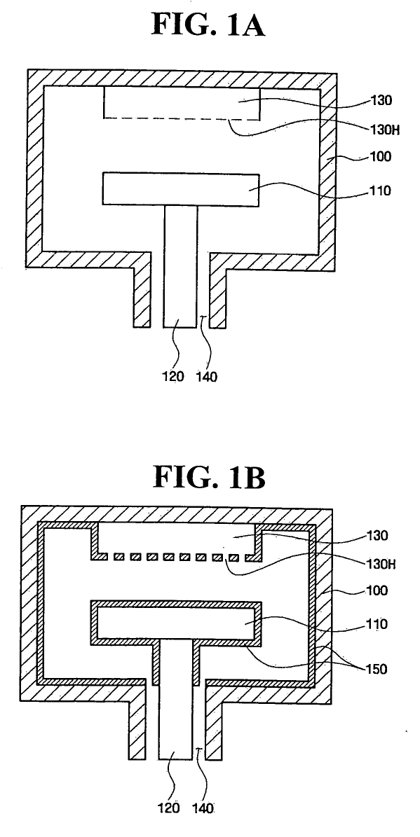

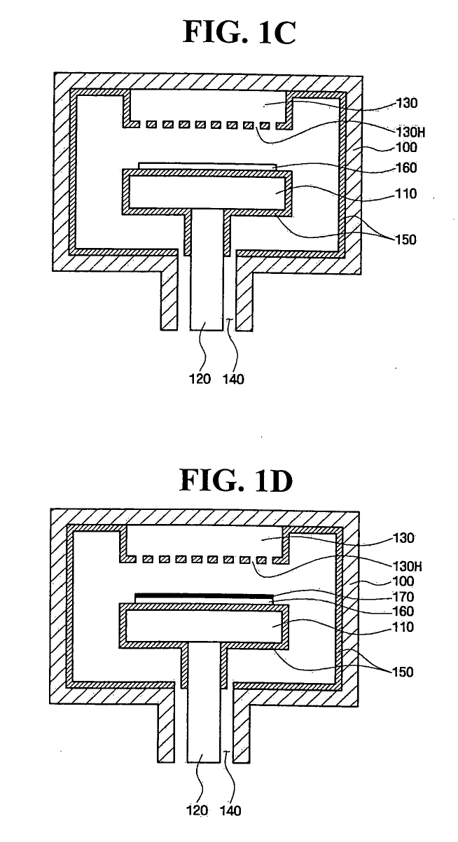

Hereinafter, a method of forming a tungsten silicide layer according to an embodiment of the invention will be described with reference to FIGS. 1A through 1D. In the description of the method that follows, certain specific processes will be set forth as working examples. However, many alternate, conventionally understood processes might be similarly used, as required by a specific application.

FIG. 1A is a sectional view schematically illustrating a CVD process chamber adapted to the performance of a fabrication method designed to form a tungsten silicide layer on a semiconductor working piece (e.g., a wafer being processed). The CVD process chamber generally includes a CVD chamber housing 100, and a susceptor 110, and a shower head 130 located within CVD chamber housing 100.

CVD chamber housing 100 defines an enclosed environment in which a CVD process may be performed during the sequence of fabrication processes used to form semiconductor devices on a wafer. The wafer is mounted on susceptor 110 within CVD chamber housing 100 in preparation of the formation of a tungsten silicide layer thereon. A heater (not shown) is typically provided to maintaining a desired temperature within CVD chamber housing 100. Additionally, a transfer mechanism 120 is provided under susceptor 110 to vertically move susceptor 110.

Shower head 130 is adapted to provide one or more CVD reaction gases into CVD chamber housing 100 in a controller manner. Shower head 130 is connected to a gas feed pipe and comprises a plurality of injection holes 130H through which supplied gas is directed onto the mounted wafer. Following performance of a CVD process, surplus gas may be exhausted through a discharge vent 140.

As necessary, the interior of CVD chamber housing 100 may be dried and cleaned using, for example, a gas such as NF3 before each CVD process. Following this optional cleaning step, a pre-coating layer 150 may be formed around the interior of CVD chamber housing 100. Referring to FIG. 1B, pre-coating layer 150 forms on exposed interior portions of CVD chamber housing 100, susceptor 110, and shower head 130.

In this regard, a tungsten source gas and a silicon source gas may be injected through shower head 130 into the CVD process chamber to form pre-coating layer 150. In one embodiment of the invention, a flow ratio (A/B) of tungsten source gas (A) to silicon source gas (B) may be maintained at 1/50 or less so as to form a tungsten silicide-type pre-coating layer useful during a subsequent formation of a tungsten silicide layer having high silicon content on the wafer being process. If the flow ratio is maintained as described above, the generation of contamination particles may be minimized during the subsequent tungsten silicide layer formation process. However, if a flow rate of silicon source gas is too much higher than that of the tungsten source gas, the resulting amount of excessive silicon may generate contamination particles. Accordingly, in certain embodiments of the invention, the flow ratio is preferably 1/500 or more. In this context, a tungsten silicide layer having a high silicon content implies that the ratio of tungsten to silicon ranges between about 1:5 to 1:15, for example.

Dichlorosilane (SiH2Cl2; DCS), monosilane (SiH4), or a mixture thereof may be used as the silicon source gas. The tungsten source gas may be WF6, or a similar gas.

Assuming the use of these source gases to form the foregoing tungsten silicide layer, the temperature of the CVD process chamber is raised to about 600° C. or higher in order to form pre-coating layer 150. In comparison with the tungsten source gas, since the degree of decomposition for the silicon source gas increases as the temperature is increased to 600° C. or higher, it is possible to form a tungsten silicide layer having a relatively high silicon component content. Further, the temperature may be controlled to about 900° C. or lower in consideration of a subsequent process and economic efficiency of the process. Additionally, the pressure of the CVD process chamber may be maintained at about 0.5 to 3 Torr during the formation of pre-coating layer 150.

As described above, pre-coating layer 150 formed under the above-mentioned conditions has been found to be useful as a pre-coating layer for the formation of a tungsten silicide layer having high silicon content—for example, a tungsten silicide layer having a ratio of tungsten to silicon ranging from about 1:5 to 1:15. That is to say, since the pre-coating layer has excellent adhesion properties with the tungsten silicide layer having the above-mentioned composition, it is possible to suppress the generation of contamination particles during the deposition of the tungsten silicide layer.

Next, as shown in FIG. 1C, a wafer 160 is loaded into CVD process chamber and mounted on susceptor 110. Wafer 160 may be a bare semiconductor substrate or a semiconductor substrate having one or more material layers or semiconductor elements previously formed thereon. In particular, wafer 160 is loaded onto an upper portion of susceptor 110 on which pre-coating layer 150 has been formed using a lift mechanism (not shown).

Next, as shown in FIG. 1D, a tungsten silicide layer 170 is formed on wafer 160.

In particular, a tungsten source gas and a silicon source gas may be injected through shower head 130 to form tungsten silicide layer 170. In the working example, tungsten silicide layer 170 is formed such that the ratio of tungsten atoms to silicon atoms in the tungsten silicide layer ranges from about 1:5 to 1:15 in view of the suppression of unnecessary silicidation provided by the foregoing exemplary method. Tungsten silicide layer 170 and a method of producing the same are more fully disclosed in commonly assigned Korean Patent Application No. 10-2005-0004196, the subject matter of which is hereby incorporated by reference.

Tungsten silicide layer 170 may be used, for example, as an ohmic contact layer between a polysilicon layer and a metal layer in the formation of a gate electrode or a contact. Since tungsten silicide layer 170 may be formed in accordance with an embodiment of the invention with a content ratio of silicon to tungsten of about 1:5 or more, it is possible to suppress over silicidation of an upper portion of the constituent metal layer. However, a content ratio of silicon to tungsten higher than 1:15 will result in deterioration of desired resistance characteristics. Thus, the content of tungsten silicide layer 170 may be optimized in consideration of tungsten.

As described above, pre-coating layer 150 formed on the interior portions of the CVD process chamber is optimally designed so that tungsten silicide layer 170 may have an optimized tungsten and silicon content. It is thus possible to suppress the generation of contamination particles during the CVD process.

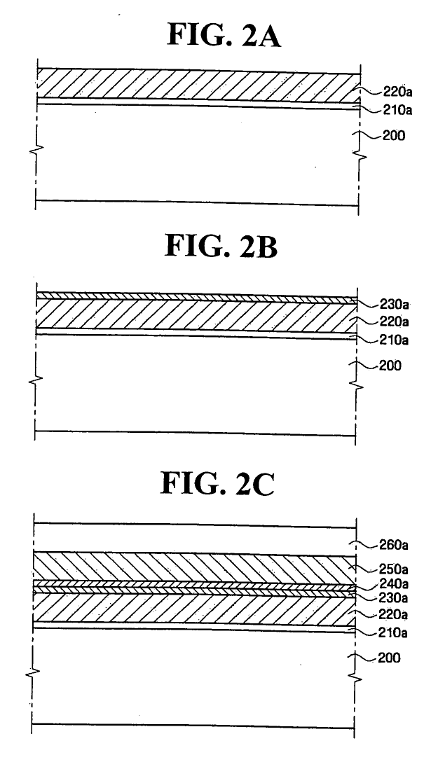

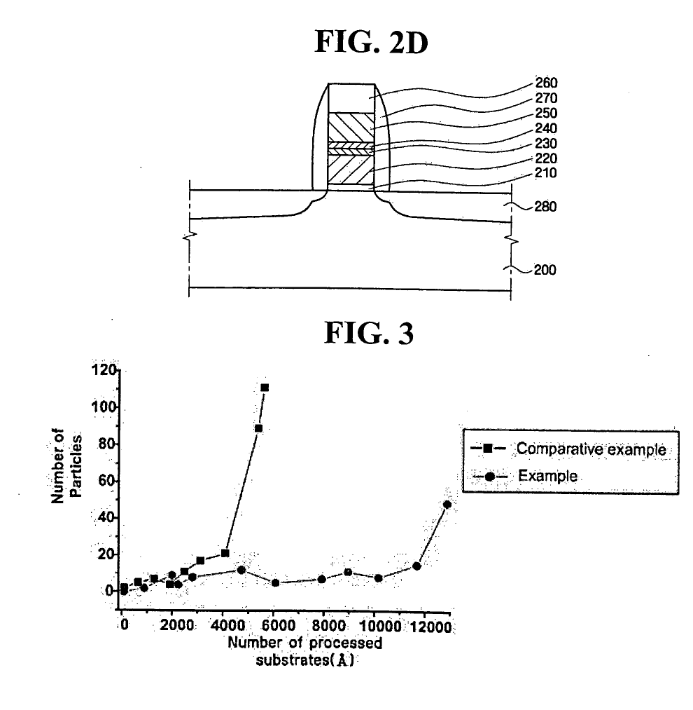

Hereinafter, a description will be given of a method of fabricating a semiconductor element using a method of forming a tungsten silicide layer according to an embodiment of the invention with reference to FIGS. 2A through 2D. In the method of fabricating the semiconductor element according to the embodiment of the present invention, the method of forming the tungsten silicide layer may be identical to the method described above, thus repetition of description will be omitted.

First, a pre-coating layer including tungsten silicide is formed on the interior of the CVD process chamber. In this connection, a flow ratio (A/B) of a tungsten source gas (A) and a silicone source gas (B) may be controlled to be 1/50 or less, and in some embodiments preferably about 1/500 or more. Before formation of the pre-coating, dry cleaning process may be conducted using a gas such as NF3 if necessary.

Pre-coating layer 150 is designed so that a condition of a CVD device is optimized to efficiently obtain a tungsten silicide layer having high silicon content, and it is possible to suppress any increase in the generation of contamination particles as the CVD process advances.

A semiconductor substrate 200 provided with a gate insulating layer 210a and a polysilicon layer 220a, as shown in FIG. 2A, is then loaded into the CVD process chamber in which pre-coating layer 150 is formed—the wafer comprising semiconductor substrate 200 has been previously and mounted on an upper part of susceptor 110.

Semiconductor substrate 200 may be formed from one or more semiconductor materials selected from the group consisting of Si, Ge, SiGe, GaP, GaAs, SiC, SiGeC, InAs, and InP, or a SOI (silicon on insulator) substrate.

Gate insulating layer 210a may be formed from a silicon oxide layer produced by a thermal oxidation process of the semiconductor substrate 200, SiON, GexOyNz, GexSiyOz, a high dielectric material, a mixture thereof, or a laminate thereof. Possible high dielectric materials useful to this purpose include HfO2, ZrO2, Al2O3, Ta2O5, hafnium silicate, zirconium silicate, or a mixture thereof.

Polysilicon layer 220a may be an n-type or a p-type doped polysilicon layer.

Subsequently, as shown in FIG. 2B, a tungsten silicide layer 230a, serving as an ohmic contact layer, is formed on polysilicon layer 220a. A tungsten source gas and a silicon source gas may be injected through shower head 130 into the CVD process chamber to form tungsten silicide layer 230a. In this connection, a ratio of tungsten to silicon in the resulting tungsten silicide layer may range from about 1:5 to 1:15.

In tungsten silicide layer 230a, since content ratio of silicon to tungsten may be set to 1:5 or more, it is possible to suppress over silicidation of the upper portion of the metal layer. However, if a content ratio of silicon to tungsten is higher than 1:15, resistance characteristics of a gate electrode may deteriorate.

Additionally, the thickness of tungsten silicide layer 230a may range from about 30 to 200 Å, as defined in terms of the desired resistance and in order to prevent over silicidation.

Subsequently, as shown in FIG. 2C, a metal barrier layer 240a and a refractory metal layer 250a are sequentially laminated on tungsten silicide layer 230a. Furthermore, a hard mask layer 260a may optionally be formed.

Metal barrier layer 240a prevents silicidation of refractory metal layer 250a by a subsequently applied thermal annealing process. Accordingly, metal barrier layer 240a may include one or more metal nitrides, such as tungsten nitrides, titanium nitrides, tantalum nitrides, and boron nitrides.

Refractory metal layer 250a may include refractory metal having a melting point higher than that of iron (1539° C.). Exemplary refractory metals include tungsten (W), rhenium (Re), tantalum (Ta), osmium (Os), molybdenum (Mo), niobium (Nb), vanadium (V), hafnium (Hf), zirconium (Zr), and titanium (Ti). In consideration of its ease of application in the fabrication of many semiconductor elements, tungsten may be well suited to many embodiments of the invention as refractory metal layer 250a.

Subsequently, as shown in FIG. 2D, the hard mask layer, refractory metal layer, metal barrier layer, tungsten silicide layer, polysilicon layer, and gate insulating layer may be sequentially patterned to complete the gate electrode structure. A spacer 270 may be formed on sidewalls of the resulting gate electrode structure, and source and drain regions 280 may be formed in substrate portions proximate the gate electrode structure.

Subsequently, conventionally understood fabrication processes may be applied to form connection wiring associated with the gate electrode structure, to form a passivation layer on the semiconductor substrate, and eventually package semiconductor elements.

Hereinafter, specific examples of processes adapted to the formation of a tungsten silicide layer consistent with the present invention will be described, along with evaluation results for contamination particles generated with respect to the comparative examples.

In a first example, a CVD process chamber was pre-coated at 650° C. and 0.9 Torr for 1200 sec while the flow rate of DCS was set to 200 sccm and the flow rate of WF6 was set to 2 sccm. Next, a semiconductor substrate was loaded and maintained at 650° C. and 0.9 Torr for 65 sec while the flow rate of DCS was set to 300 sccm and the flow rate of WF6 was set to 2 sccm to form a tungsten silicide layer (80 Å).

In a second comparative example, a CVD process chamber was pre-coated at 600° C. and 1.2 Torr for 50 sec while the flow rate of DCS was set to 250 sccm and the flow rate of WF6 was set to 12 sccm. The CVD process chamber was additionally pre-coated at 600° C. and 1.2 Torr for 250 sec while the flow rate of DCS was set to 300 sccm and the flow rate of WF6 was set to 19 sccm. Next, a semiconductor substrate was loaded and maintained at 650° C. and 0.9 Torr for 65 sec while the flow rate of DCS was set to 300 sccm and the flow rate of WF6 was set to 2 sccm to form a tungsten silicide layer (80 Å).

The number of contamination particles generated with respect to the total deposition thickness (the number of processed substrates) was evaluated using the above-mentioned example and comparative example, and the results are shown in FIG. 3.

Referring to FIG. 3, in the case in which the tungsten silicide layer is formed in the example according to an embodiment of the present invention, it can be seen that the number of particles is maintained at about 20 or less until the total deposition thickness (the number of processed substrates) is about 12000 Å(about 150 sheets).

On the other hand, in the case in which the tungsten suicide layer is formed in the comparative example, it can be seen that the number of particles is rapidly increased when the total deposition thickness (the number of processed substrates) is about 4000 to 5000 Å(about 60 sheets).

Although the present invention has been described in connection with several exemplary embodiments, it will be apparent to those skilled in the art that various modifications and changes may be made thereto without departing from the scope of the invention as defined by the following claims. Therefore, it should be understood that the above embodiments are not limitative, but illustrative.

As described above, according to embodiments of the present invention, generation of contamination particles may be suppressed during a CVD process, thus it is possible to efficiently provide a tungsten silicide layer having increased silicon content in terms of economic efficiency of the process while also assuring reliability of the incorporating semiconductor element.

What is claimed is:

1. A method of forming a tungsten silicide layer on a semiconductor substrate in a Chemical Vapor Deposition (CVD) process chamber, the method comprising:
forming a pre-coating layer on the interior of the CVD process chamber by injecting a tungsten source gas (A) and a silicon source gas (B) at a flow ratio (A/B) of 1/50 or less; and thereafter,
loading the semiconductor substrate into the CVD process chamber; and
injecting additional tungsten source gas and silicon source gas to form the tungsten silicide layer on the semiconductor substrate.

2. The method of claim 1, wherein forming the pre-coating layer is performed at a temperature of 600° C. or higher.

3. The method of claim 1, wherein forming the pre-coating layer is performed at a pressure ranging between 0.5 to 3 Torr.

4. The method of claim 1, wherein the tungsten silicide layer is formed with a content ratio of tungsten to silicon ranging between about 1:5 to 1:15.

5. The method of claim 1, wherein the silicon source gas is SiH2Cl2, SiH4, or a gas mixture of SiH2Cl2 and SiH4.

6. The method of claim 1, wherein the tungsten source gas is WF6.

7. The method of claim 1, further comprising:
before forming the pre-coating layer, dry cleaning the interior of the CVD process chamber.

8. A method of fabricating a semiconductor element on a semiconductor substrate, the method comprising:
forming a pre-coating layer in a Chemical Vapor Deposition (CVD) process chamber by injecting a tungsten source gas (A) and a silicon source gas (B) at a flow ratio (A/B) of 1/50 or less; and thereafter,
loading the semiconductor substrate into the CVD process chamber, wherein the semiconductor substrate comprises a gate insulating layer and a polysilicon layer formed on the gate insulating layer; and
injecting additional tungsten source gas and silicon source gas to form a tungsten silicide layer on the polysilicon layer.

9. The method of claim 8, wherein forming the pre-coating layer is performed at a temperature of 600° C. or higher.

10. The method of claim 8, wherein forming the pre-coating layer is performed at a pressure ranging between about 0.5 to 3 Torr.

11. The method of claim 8, wherein the tungsten silicide layer is formed with a content ratio of tungsten to silicon ranging between about 1:5 to 1:15.

12. The method of claim 8, wherein the silicon source gas is SiH2Cl2, SiH4, or a gas mixture of SiH2Cl2 and SiH4.

13. The method of claim 8, wherein the tungsten source gas is WF6.

14. The method of claim 8, further comprising:
before forming the pre-coating layer, dry cleaning the CVD process chamber.

15. The method of claim 8, further comprising:
sequentially forming a metal barrier layer and a refractory metal layer on the tungsten silicide layer.
